(19) United States
(12) Patent Application Publication
(10) Pub. No.: US 2026/0011602 A1
(43) Pub. Date: Jan. 8, 2026

(54) ION IMPLANTATION FOR ETCH RATE REDUCTION DURING BACKSIDE CONTACT FORMATION

(71) Applicant: Applied Materials, Inc., Santa Clara, CA (US)

(72) Inventors: Yan ZHANG, Westford, MA (US); Baonian GUO, Andover, MA (US); Kyu-Ha SHIM, Andover, MA (US)

(73) Assignee: Applied Materials, Inc., Santa Clara, CA (US)

(21) Appl. No.: 18/762,329

(22) Filed: Jul. 2, 2024

(51) Int. Cl. H01L 21/768; H01L 29/08; H01L 29/66

(52) U.S. Cl. CPC H01L 21/76825; H01L 21/76805; H10D 62/151; H10D 64/015; H10D 64/021

(57) ABSTRACT

Approaches of the disclosure relate to methods for forming self-aligned backside contacts in a semiconductor device. One method may include forming a trench in a stack of layers, wherein the stack of layers comprises a plurality of alternating first layers and second layers atop a base layer, and wherein the trench is defined by a set of sidewalls and a bottom extending between the set of sidewalls. The method may further include implanting the bottom of the trench to form an etch stop layer within the base layer, forming a recess in the base layer by removing the base layer selective to the etch stop layer, and filling the recess with a temporary material. The method may further include depositing a source/drain material within the trench, wherein the source/drain material is formed over the temporary material.

### FIELD OF THE DISCLOSURE

The present embodiments relate to semiconductor device patterning, and more particularly, to devices and methods for forming self-aligned backside contacts in a semiconductor device.

### BACKGROUND OF THE DISCLOSURE

As integrated circuit (IC) technologies progress towards smaller technology nodes, multigate devices have been used to improve gate control by increasing gate-channel coupling, reducing off-state current, and reducing short-channel effects. A multigate device generally refers to a device having a gate structure, or portion thereof, disposed over more than one side of a channel region. Field effect transistors (FETs) and gate-all-around (GAA) transistors, both also referred to as non-planar transistors, are examples of multigate devices that provide high performance and low leakage applications. The channel region of GAA transistors may be formed from nanowires, nanosheets (NS), or other nanostructures.

For continuous scaling, backside power distributed networks (BSPDN) are being adopted in which contacts are formed from the backside (BSCON). However, backside contact trench mis-alignment due to patterning and stress is a critical issue in the BSPDN process. Trench placeholders have been used in some approaches to solve this mis-alignment issue. However, the depth of the placeholder, and thus the backside contact height, is hard to control, which may lead to significant process and performance variations.

Accordingly, improved approaches are needed to form transistor backside contacts.

### SUMMARY

This Summary is provided to introduce a selection of concepts in a simplified form that are further described below in the Detailed Description. This Summary is not intended to identify key features or essential features of the claimed subject matter, nor is it intended as an aid in determining the scope of the claimed subject matter.

In one aspect, a method may include forming a trench in a stack of layers, wherein the stack of layers comprises a plurality of alternating first layers and second layers atop a base layer, and wherein the trench is defined by a set of sidewalls and a bottom extending between the set of sidewalls. The method may further include implanting the bottom of the trench to form an etch stop layer within the base layer, forming a recess in the base layer by removing the base layer selective to the etch stop layer, and filling the recess with a temporary material. The method may further include depositing a source/drain material within the trench, wherein the source/drain material is formed over the temporary material.

In another aspect, a method for forming a backside contact in a semiconductor device may include forming a trench in a stack of layers, wherein the stack of layers comprises a plurality of alternating first layers and second layers atop a base layer, and wherein the trench is defined by a set of sidewalls and a bottom extending between the set of sidewalls. The method may further include implanting the bottom of the trench to form an etch stop layer within the base layer, forming a recess in the base layer by removing the base layer selective to the etch stop layer, and filling the recess with a temporary material. The method may further include depositing a source/drain material within the trench, wherein the source/drain material is formed over the temporary material, removing the temporary material from the recess after the source/drain material is formed within the trench, and depositing a metal within the recess to form the backside contact.

In yet another aspect, a method for forming a backside contact in a semiconductor device may include forming a trench in a stack of layers, wherein the stack of layers comprises a plurality of alternating first layers and second layers atop a base layer, and wherein the trench is defined by a set of sidewalls and a bottom extending between the set of sidewalls. The method may further include forming a liner along the set of sidewalls, implanting the bottom of the trench to form an etch stop layer within the base layer, forming a recess in the base layer by removing the base layer selective to the etch stop layer, and filling the recess with a temporary material. The method may further include depositing a source/drain material within the trench, wherein the source/drain material is formed over the temporary material, removing the temporary material from the recess after the source/drain material is formed within the trench, and depositing a metal within the recess to form the backside contact.

### BRIEF DESCRIPTION OF THE DRAWINGS

The accompanying drawings illustrate exemplary approaches of the disclosure, including the practical application of the principles thereof, as follows:

FIG. 1 is a cross-sectional view of a stack of layers of a device structure according to embodiments of the present disclosure;

FIG. 2 is a cross-sectional view of the device structure including a trench formed therein, according to embodiments of the present disclosure;

FIG. 3 is a cross-sectional view of the device structure during an ion implant, according to embodiments of the present disclosure;

FIG. 4 is a cross-sectional view of the device structure during an etch process, according to embodiments of the present disclosure;

FIG. 5 is a cross-sectional view of the device structure following formation of a temporary material within a recess, according to embodiments of the present disclosure;

FIG. 6 is a cross-sectional view of the device structure following formation of a source/drain material within the trench, according to embodiments of the present disclosure;

FIG. 7 is a cross-sectional view of the device structure following formation of a backside contact, according to embodiments of the present disclosure;

FIG. 8 illustrates a perspective view of an example processing system, according to embodiments of the present disclosure.

The drawings are not necessarily to scale. The drawings are merely representations, not intended to portray specific parameters of the disclosure. The drawings are intended to depict exemplary embodiments of the disclosure, and therefore are not to be considered as limiting in scope. In the drawings, like numbering represents like elements.

Furthermore, certain elements in some of the figures may be omitted, or illustrated not-to-scale, for illustrative clarity. The cross-sectional views may be in the form of “slices”, or “near-sighted” cross-sectional views, omitting certain background lines otherwise visible in a “true” cross-sectional view, for illustrative clarity. Furthermore, for clarity, some reference numbers may be omitted in certain drawings.

### DETAILED DESCRIPTION

Methods, systems, and devices in accordance with the present disclosure will now be described more fully hereinafter with reference to the accompanying drawings, where various embodiments are shown. The methods, systems, and devices may be embodied in many different forms and are not to be construed as being limited to the embodiments set forth herein. Instead, these embodiments are provided so the disclosure will be thorough and complete, and will fully convey the scope of the methods to those skilled in the art.

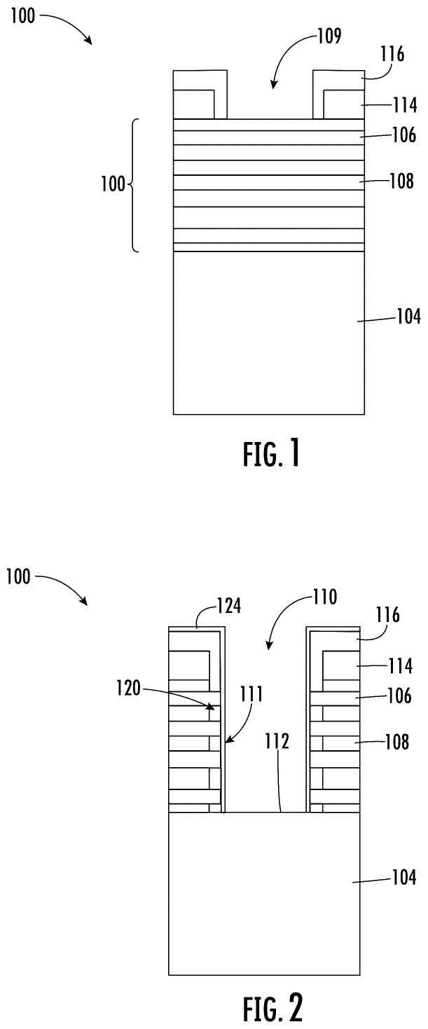

With reference to FIG. 1, an approach for forming a semiconductor device (hereinafter “device”) 100 according to one or more embodiments will be described. Although non-limiting, the device 100 may be a GAA device structure, a vertical GAA device structure, or a horizontal GAA device structure. As shown, the device 100 may include a stack 102 including a plurality of alternating first layers 106 and second layers 108 formed over a base layer 104.

The stack 102 may be part of a nanosheet, wherein the term “nanosheet,” refers to a sheet or a layer having nanoscale dimensions. Further, the term nanosheet is meant to encompass other nanoscale structures such as nanowires. For instance, nanosheet can refer to a nanowire with a larger width, and/or nanowire can refer to a nanosheet with a smaller width, and vice versa.

In various embodiments, the plurality of alternating first layers 106 and second layers 108 may include between two (2) and ten (10) first layers 106 and between two (2) and ten (10) second layers 108. A composition of the first layers 106 may be different than a composition of the second layers 108 to achieve etching selectivity and/or different oxidation rates during subsequent processing, for example. In some embodiments, the plurality of alternating first layers 106 and second layers 108 may include different materials, different constituent atomic percentages, different constituent weight percentages, and/or other different characteristics to achieve desired etching selectivity.

In the present embodiment, the first layers 106 may include silicon (Si) and the second layers 108 may include silicon germanium (SiGe), which has a different etch selectivity than silicon. Although non-limiting, a thickness of each first layer 106 may be about 1 nm to about 10 nm, a thickness of each second layer 108 may be about 1 nm to about 10 nm, and the two thicknesses can be the same or different. Although non-limiting, the plurality of alternating first layers 106 and second layers 108 may be epitaxially grown in the depicted interleaving and alternating configuration, layer-by-layer, until a desired number of semiconductor layers is reached.

According to an exemplary embodiment, the base layer 104 may be a bulk semiconductor substrate. As used herein, the term “bulk semiconductor substrate” refers to a substrate in which the entirety of the substrate is comprised of a semiconductor material. The bulk semiconductor substrate may comprise any suitable semiconducting material and/or combinations of semiconducting materials for forming a semiconductor structure. For example, the semiconducting layer may comprise one or more materials such as crystalline silicon (e.g., Si<100> or Si<111>), silicon oxide, strained silicon, silicon germanium, doped or undoped polysilicon, doped or undoped silicon wafers, patterned or non-patterned wafers, doped silicon, germanium, gallium arsenide, or other suitable semiconducting materials. In some embodiments, the semiconductor material is silicon (Si). In one or more embodiments, the base layer 104 may include a semiconductor material, e.g., silicon (Si), carbon (C), germanium (Ge), silicon germanium (SiGe), germanium tin (GeSn), other semiconductor materials, or any combination thereof. In one or more embodiments, the base layer 104 may include one or more of silicon (Si), germanium (Ge), gallium (Ga), arsenic (As), or phosphorus (P). Although a few examples of materials from which the substrate may be formed are described herein, any material that may serve as a foundation upon which passive and active electronic devices (e.g., transistors, memories, capacitors, inductors, resistors, switches, integrated circuits, amplifiers, optoelectronic devices, or any other electronic devices) may be built falls within the spirit and scope of the present disclosure.

In some embodiments, the semiconductor material may be a doped material, such as n-doped silicon (n-Si), or p-doped silicon (p-Si). In some embodiments, the substrate may be doped using any suitable process such as an ion implantation process. As used herein, the term “n-type” refers to semiconductors that are created by doping an intrinsic semiconductor with an electron donor element during manufacture. The term n-type comes from the negative charge of the electron. In n-type semiconductors, electrons are the majority carriers and holes are the minority carriers. As used herein, the term “p-type” refers to the positive charge of a well (or hole). As opposed to n-type semiconductors, p-type semiconductors have a larger hole concentration than electron concentration. In p-type semiconductors, holes are the majority carriers and electrons are the minority carriers. In one or more embodiments, the dopant is selected from one or more of boron (B), gallium (Ga), phosphorus (P), arsenic (As), other semiconductor dopants, or combinations thereof.

A gate structure 114 (e.g., dummy gate) may also be formed over the first layers 106 and the second layers 108, on opposite sides of a recess 109. The gate structure 114 may include a sacrificial gate having a gate material layer and an interlayer dielectric (ILD) 116 formed atop the gate material layer. In some embodiments, the gate material layer may be an amorphous silicon (a-Si) or a polysilicon. Embodiments herein are not limited in this context, however.

As shown in FIG. 2, the first and second layers 106, 108 may be processed (e.g., etched) to form a trench 110. The trench 110 may extend to a top surface 112 of the base layer 104, and may have a set of opposing sidewalls 111. The first and second layers 106, 108 may be patterned by any suitable method to form the trench 110. For example, the stack 102 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. In this case, the width of the trench 110 may be determined by the ILD 116 formed atop the gate material layer.

A lateral selective etch may be performed to trim the second layers 108 horizontally (e.g., by a few nm) to form gaps between Si nanosheets. One or more low-k materials may then be used to fill these gaps and form an inner spacer 120. In various non-limiting embodiments, low-k materials may include a dielectric having a dielectric constant less than about 7, for example, less than about 5 or even less than about 2.5, such as carbon containing silicon materials such as silicon oxycarbides (SiOC) or silicon carbides, silicon nitrides (SiN) or carbon containing silicon nitride materials (SiCN), and/or boron nitride (BN), silicon boron nitride (SiBN), silicon boron carbide nitride (SiBCN), carbon doped silicon oxide, fluorine doped oxide, porous dielectric, or combinations thereof. As shown, the inner spacer 120 is generally formed along an exposed sidewall surface of each of the second layers 108. A liner (e.g., dielectric) 124 may then be formed over the sidewalls 111 of the trench 110, including over the inner spacer 120.

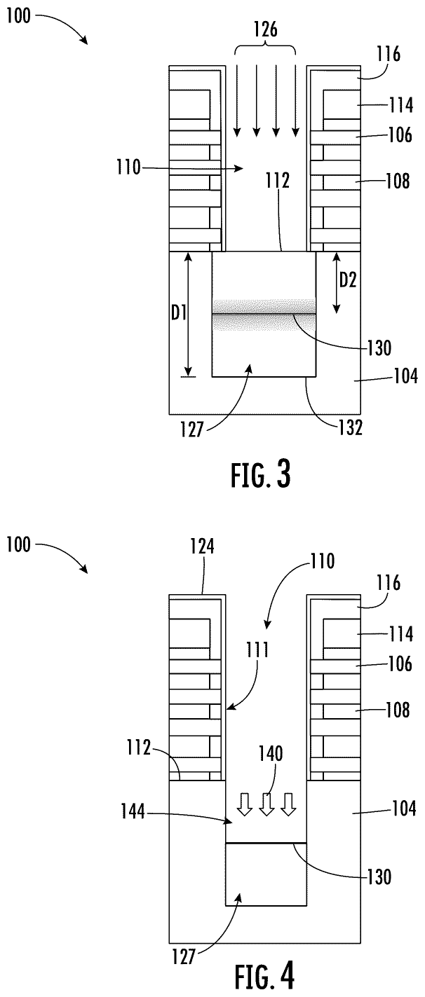

As shown in FIG. 3, an ion treatment 126 may then be performed in which ions are delivered into the upper surface 112 of the base layer 104, within the trench 110. An ion dopant species of the ion treatment 126 may be boron (B), or may be any species that reduces anisotropic etch rate in the base layer 104. The ion treatment 126 may form an area 127 of varied dopant concentration within the base layer 104, to a depth ‘D1’. Within the area 127 of varied dopant concentration, an etch stop layer 130 may be formed within the base layer 104 at a point or depth corresponding to the highest dopant concentration. As shown, the etch stop layer 130 may be formed to a depth ‘D2’. In the embodiment shown, dopant concentration may generally increase between the upper surface 112 of the base layer 104 and the etch stop layer 130, and may generally decrease between the etch stop layer 130 and a bottom 132 of the area 127 of varied dopant concentration. It will be appreciated that D1 and D2, as well as the gradient dopant concentration, may vary depending various characteristics of the ion treatment 126 including, but not limited to, dopant species, implant energy, implant temperature, implant angle, implant dose, etc. In exemplary embodiments, the ion treatment 126 may be medium or high current, room temperature or high temperature (e.g., Thermion implant), and delivered vertically. For example, when a room temperature implant is desired, ions (e.g., boron) may be delivered between approximately 15-25° C., and when a high temperature implant is desired, ions (e.g., boron) may be delivered into the trench 110 while a wafer pedestal (not shown) supporting the device 100 is maintained at a temperature greater than 400° C. In some embodiments, a thermal treatment (e.g., anneal) may be performed on the device 100 following the ion treatment 126 to activate the dopants, particularly along the etch stop layer 130.

As shown in FIG. 4, a removal process 140 may be performed within the trench 110 to remove a portion of the base layer 104. In some embodiments, the removal process 140 may be an anisotropic etch performed into the upper surface 112 of the base layer 104, the etch being selective to the etch stop layer 130. As a result, a recess 144 is formed within the base layer 104.

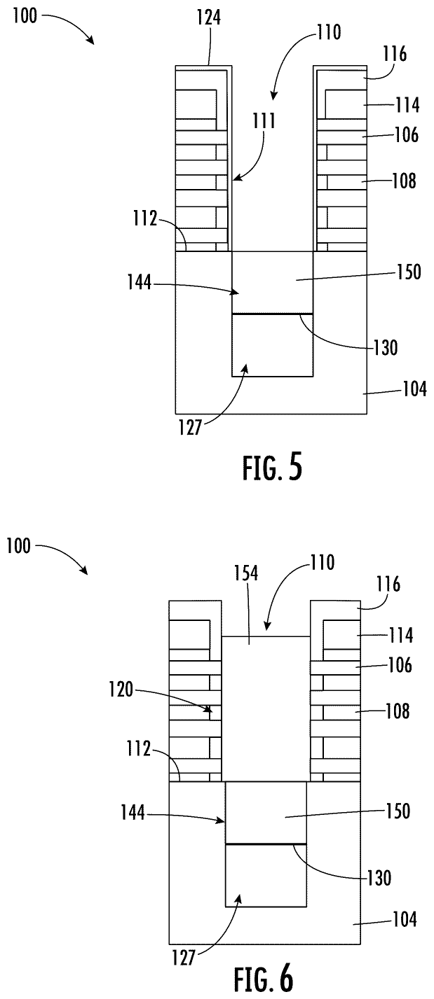

As shown in FIG. 5, the recess 144 may then be filled with a temporary material 150. Although non-limiting, the temporary material 150 may be a dummy fill formed to be approximately co-planar with the upper surface 112 of the base layer 104. The temporary material may be formed directly atop the etch stop layer 130.

As shown in FIG. 6, the liner 124 may be removed, and a source/drain (S/D) material 154 may be formed within the trench 110. As shown, the S/D material 154 may be formed directly atop the temporary material 150. In the embodiment shown, the S/D material 154 may be formed using an epitaxy process such as chemical vapor deposition (CVD) techniques (e.g., vapor phase epitaxy and/or Ultra-High Vacuum CVD), molecular beam epitaxy, other suitable epitaxial growth processes, or combinations thereof, to form the S/D material 154. The epitaxy process can use gaseous and/or liquid precursors.

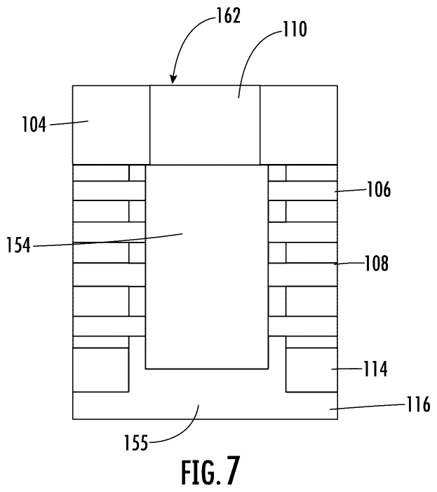

As shown in FIG. 7, a dielectric layer 155 may be formed over the source/drain material 154, the device 100 may be flipped, and the base layer 104 thinned (e.g., etched or planarized). Advantageously, the etch stop layer 130 and the temporary material 150 (not shown) prevent uncontrolled removal of the base layer 104. The temporary material 150 may then be removed from the recess 144 using, e.g., a wet etch, wherein the wet etch exposes an upper surface of the S/D material 154. A metal 160 may then be formed in the recess 144 to form a backside contact 162. Although non-limiting, the metal 160 may be cobalt, tungsten, copper, ruthenium, alloys thereof, or a combination thereof, and may be deposited by CVD, ALD, PVD, or another deposition technique.

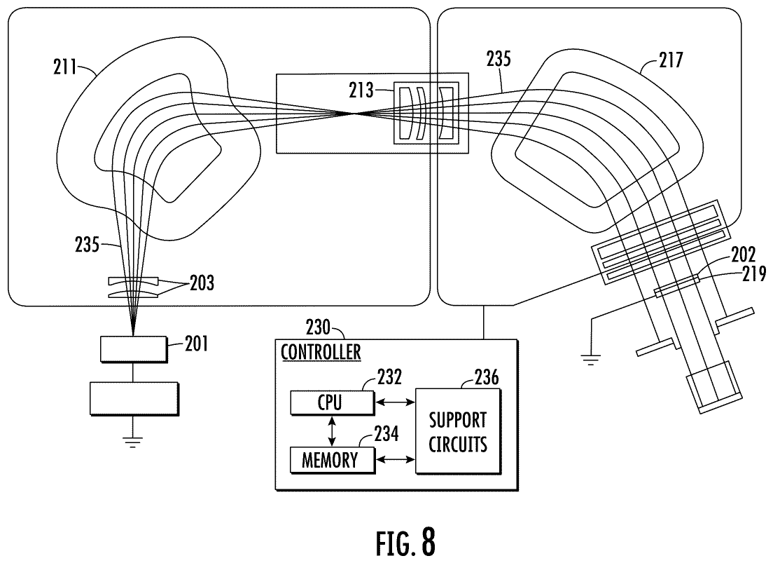

FIG. 8 illustrates a schematic diagram of a processing apparatus 200 useful to perform processes described herein. One example of a beam-line ion implantation processing apparatus is the Varian VIISTA® Trident, available from Applied Materials Inc., Santa Clara, CA. The processing apparatus 200 may include an ion source 201 for generating ions. For example, the ion source 201 may provide an ion implant, such as the ion treatment 126 demonstrated in FIG. 3. The processing apparatus 200 may also include a series of beam-line components. Examples of beam-line components may include extraction electrodes 203, a magnetic mass analyzer 211, a plurality of lenses 213, and a beam parallelizer 217. The processing apparatus 200 may also include a platen 219 for supporting a substrate 202 to be processed. The substrate 202 may be the same or different as the substrate layer 102 described above. The substrate 202 may be moved in one or more dimensions (e.g., translate, rotate, tilt, etc.) by a component sometimes referred to as a pedestal or “roplat” (not shown). It is also contemplated that the processing apparatus 200 may be configured to perform heated implantation processes to provide for improved control of implantation characteristics, such as the ion trajectory and implantation energy utilized to dope the substrate.

In operation, ions of the desired species, for example, dopant ions of boron, are generated and extracted from the ion source 201. Thereafter, the extracted ions 235 travel in a beam-like state along the beam-line components and may be implanted in the substrate 202. Similar to a series of optical lenses that manipulate a light beam, the beam-line components manipulate the extracted ions 235 along the ion beam. In such a manner, the extracted ions 235 are manipulated by the beam-line components while the extracted ions 235 are directed toward the substrate 202. It is contemplated that the apparatus 200 may provide for improved mass selection to implant desired ions while reducing the probability of undesirable ions (impurities) being implanted in the substrate 202.

More specifically, during an ion treatment, an ion beam is extracted through the extraction aperture. The trajectories of ions within the ion beam may be mutually parallel to one another or may lie within a narrow angular range, such as within 10 degrees of one another or less. Thus, the value of the angle may represent an average value of incidence angle where the individually trajectories vary up to several degrees from the average value. The ion beam may be extracted when a voltage difference is applied using bias supply between the plasma chamber and substrate 202, as in known systems. The bias supply may be coupled to the process chamber, for example, where the process chamber and substrate 202 are held at the same potential. In various embodiments, the ion beam may be extracted as a continuous beam or as a pulsed ion beam as in known systems. For example, the bias supply may be configured to supply a voltage difference between plasma chamber and process chamber, as a pulsed DC voltage, where the voltage, pulse frequency, and duty cycle of the pulsed voltage may be independently adjusted from one another.

In some embodiments, the processing apparatus 200 can be controlled by a processor-based system controller such as controller 230. For example, the controller 230 may be configured to control beam-line components and processing parameters associated with beam-line ion implantation processes. The controller 230 may include a programmable central processing unit (CPU) 232 that is operable with a memory 234 and a mass storage device, an input control unit, and a display unit (not shown), such as power supplies, clocks, cache, input/output (I/O) circuits, and the like, coupled to the various components of the processing apparatus 200 to facilitate control of the substrate processing. The controller 230 also includes hardware for monitoring substrate processing through sensors in the processing apparatus 200, including sensors monitoring the substrate position and sensors configured to receive feedback from and control a heating apparatus coupled to the processing apparatus 200. Other sensors that measure system parameters such as substrate temperature and the like, may also provide information to the controller 230.

To facilitate control of the processing apparatus 200 described above, the CPU 232 may be one of any form of general-purpose computer processor that can be used in an industrial setting, such as a programmable logic controller (PLC), for controlling various chambers and sub-processors. The memory 234 is coupled to the CPU 232 and the memory 234 is non-transitory and may be one or more of readily available memory such as random access memory (RAM), read only memory (ROM), floppy disk drive, hard disk, or any other form of digital storage, local or remote. Support circuits 236 may be coupled to the CPU 232 for supporting the processor in a conventional manner. Implantation and other processes are generally stored in the memory 234, typically as a software routine. The software routine may also be stored and/or executed by a second CPU (not shown) that is remotely located from the hardware being controlled by the CPU 232.

The memory 234 is in the form of computer-readable storage media that contains instructions, that when executed by the CPU 232, facilitates the operation of the apparatus 200. The instructions in the memory 234 are in the form of a program product such as a program that implements the method of the present disclosure. The program code may conform to any one of a number of different programming languages. In one example, the disclosure may be implemented as a program product stored on computer-readable storage media for use with a computer system. The program(s) of the program product define functions of the embodiments (including the methods described herein). Illustrative computer-readable storage media include, but are not limited to: (i) non-writable storage media (e.g., read-only memory devices within a computer such as CD-ROM disks readable by a CD-ROM drive, flash memory, ROM chips or any type of solid-state non-volatile semiconductor memory) on which information is permanently stored; and (ii) writable storage media (e.g., floppy disks within a diskette drive or hard-disk drive or any type of solid-state random-access semiconductor memory) on which alterable information is stored. Such computer-readable storage media, when carrying computer-readable instructions that direct the functions of the methods described herein, are embodiments of the present disclosure.

In various embodiments, design tools can be provided and configured to create the datasets used to pattern the semiconductor layers of the device 100, e.g., as described herein. For example, data sets can be created to generate photomasks used during lithography operations to pattern the layers for structures as described herein. Such design tools can include a collection of one or more modules and can also be comprised of hardware, software or a combination thereof. Thus, for example, a tool can be a collection of one or more software modules, hardware modules, software/hardware modules or any combination or permutation thereof. As another example, a tool can be a computing device or other appliance running software, or implemented in hardware.

As used herein, a module might be implemented utilizing any form of hardware, software, or a combination thereof. For example, one or more processors, controllers, ASICs, PLAs, logical components, software routines or other mechanisms might be implemented to make up a module. In implementation, the various modules described herein might be implemented as discrete modules or the functions and features described can be shared in part or in total among one or more modules. In other words, as would be apparent to one of ordinary skill in the art after reading the Detailed Description, the various features and functionality described herein may be implemented in any given application and can be implemented in one or more separate or shared modules in various combinations and permutations. Although various features or elements of functionality may be individually described or claimed as separate modules, one of ordinary skill in the art will understand these features and functionality can be shared among one or more common software and hardware elements.

For the sake of convenience and clarity, terms such as “top,” “bottom,” “upper,” “lower,” “vertical,” “horizontal,” “lateral,” and “longitudinal” will be understood as describing the relative placement and orientation of components and their constituent parts as appearing in the figures. The terminology will include the words specifically mentioned, derivatives thereof, and words of similar import.

Furthermore, the terms “substantial” or “substantially,” as well as the terms “approximate” or “approximately,” can be used interchangeably in some embodiments, and can be described using any relative measures acceptable by one of ordinary skill in the art. For example, these terms can serve as a comparison to a reference parameter, to indicate a deviation capable of providing the intended function. Although non-limiting, the deviation from the reference parameter can be, for example, in an amount of less than 1%, less than 3%, less than 5%, less than 10%, less than 15%, less than 20%, and so on.

Still furthermore, one of ordinary skill will understand when an element such as a layer, region, or substrate is referred to as being formed on, deposited on, or disposed “on,” “over” or “atop” another element, the element can be directly on the other element or intervening elements may also be present. In contrast, when an element is referred to as being “directly on,” “directly over” or “directly atop” another element, no intervening elements are present.

While certain embodiments of the disclosure have been described herein, the disclosure is not limited thereto, as the disclosure is as broad in scope as the art will allow and the specification may be read likewise. Therefore, the above description is not to be construed as limiting. Instead, the above description is merely as exemplifications of particular embodiments. Those skilled in the art will envision other modifications within the scope and spirit of the claims appended hereto.

What is claimed is:

1. A method, comprising:
forming a trench in a stack of layers, wherein the stack of layers comprises a plurality of alternating first layers and second layers atop a base layer, and wherein the trench is defined by a set of sidewalls and a bottom extending between the set of sidewalls;
implanting the bottom of the trench to form an etch stop layer within the base layer;
forming a recess in the base layer by removing the base layer selective to the etch stop layer;
filling the recess with a temporary material; and
depositing a source/drain material within the trench, wherein the source/drain material is formed over the temporary material.

2. The method of claim 1, further comprising performing a thermal treatment on the stack of layers and the base layer following the implanting.

3. The method of claim 1, further comprising:
removing the temporary material from the recess after the source/drain material is formed within the trench; and
depositing a metal within the recess after the temporary material is removed.

4. The method of claim 1, further comprising forming a dielectric layer over the source/drain material.

5. The method of claim 1, further comprising:
forming an inner spacer within the trench, wherein the inner spacer is formed along the plurality of alternating first layers and second layers; and
forming a liner over the inner spacer prior to forming the recess in the base layer.

6. The method of claim 5, further comprising removing the liner prior to depositing the temporary material within the recess.

7. The method of claim 1, wherein implanting the bottom of the trench comprises delivering ions into the bottom of the trench while a wafer pedestal supporting the stack of layers is maintained at a temperature greater than 400° C.

8. The method of claim 1, wherein implanting the bottom of the trench comprises delivering ions into the bottom of the trench at a room temperature between 15-25° C.

9. A method for forming a backside contact in a semiconductor device, the method comprising:
forming a trench in a stack of layers, wherein the stack of layers comprises a plurality of alternating first layers and second layers atop a base layer, and wherein the trench is defined by a set of sidewalls and a bottom extending between the set of sidewalls;
implanting the bottom of the trench to form an etch stop layer within the base layer;
forming a recess in the base layer by removing the base layer selective to the etch stop layer;
filling the recess with a temporary material;
depositing a source/drain material within the trench, wherein the source/drain material is formed over the temporary material;
removing the temporary material from the recess after the source/drain material is formed within the trench; and
depositing a metal within the recess to form the backside contact.

10. The method of claim 9, further comprising performing a thermal treatment on the stack of layers and the base layer following the implanting.

11. The method of claim 9, further comprising forming a dielectric layer over the source/drain material.

12. The method of claim 9, further comprising:
forming an inner spacer within the trench, wherein the inner spacer is formed along the plurality of alternating first layers and second layers; and
forming a liner over the inner spacer prior to forming the recess in the base layer.

13. The method of claim 12, further comprising removing the liner prior to depositing the temporary material within the recess.

14. The method of claim 9, wherein implanting the bottom of the trench comprises delivering boron ions into an upper surface of the base layer.

15. The method of claim 14, wherein the boron ions are delivered into the base layer while a wafer pedestal supporting the stack of layers is maintained at a temperature greater than 400° C.

16. A method for forming a backside contact in a semiconductor device, the method comprising:
forming a trench in a stack of layers, wherein the stack of layers comprises a plurality of alternating first layers and second layers atop a base layer, and wherein the trench is defined by a set of sidewalls and a bottom extending between the set of sidewalls;
forming a liner along the set of sidewalls;
forming an etch stop layer within the base layer by implanting the bottom of the trench after the liner is formed along the set of sidewalls;
forming a recess in the base layer by removing the base layer selective to the etch stop layer;
filling the recess with a temporary material;
depositing a source/drain material within the trench, wherein the source/drain material is formed over the temporary material;
removing the temporary material from the recess after the source/drain material is formed within the trench; and
depositing a metal within the recess to form the backside contact.

17. The method of claim 16, further comprising performing a thermal treatment on the stack of layers and the base layer following the implanting.

18. The method of claim 16, further comprising:
forming a dielectric layer over the source/drain material; and
forming an inner spacer within the trench, wherein the inner spacer is formed along the plurality of alternating first layers and second layers, wherein the liner is formed over the inner spacer.

19. The method of claim 16, further comprising removing the liner prior to depositing the temporary material within the recess.

20. The method of claim 16, wherein implanting the bottom of the trench comprises delivering boron ions into the bottom of the trench.
